(19) United States
(12) Patent Application Publication
(10) Pub. No.: US 2008/0264608 A1
(43) Pub. Date: Oct. 30, 2008

(54) COOLING MECHANISM COMPRISING A HEAT PIPE AND WATER BLOCK

(76) Inventors: Trentent Tye, Calgary (CA); Ryan Handy, Calgary (CA)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/742,587

(22) Filed: Apr. 30, 2007

(51) Int. Cl. F28D 15/00; H05K 7/20

(52) U.S. Cl. 165/104.14; 165/104.33; 165/80.4; 361/700

(57) ABSTRACT

A cooling mechanism comprises a heat pipe coupled to a water block.

### BACKGROUND

Cooling an electronic system becomes more challenging as the heat produced by the system's heat-producing components increases with evolving system designs. Space constraints within the system's chassis can make it difficult to implement a heat removal mechanism sufficient to adequately cool the system.

### BRIEF DESCRIPTION OF THE DRAWINGS

For a detailed description of exemplary embodiments of the invention, reference will now be made to the accompanying drawings in which:

FIG. 1 shows a cooling mechanism comprising a component block, water block and heat pipe in accordance with various embodiments; and

FIG. 2 shows an embodiment of a portion of the component block and/or water block of FIG. 1.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection. The term “system” refers to a combination of two or more components. A system may comprise, for example, the combination of a server and a client communicatively coupled thereto, or a server alone, a client alone, or a subsystem within a computer.

### DETAILED DESCRIPTION

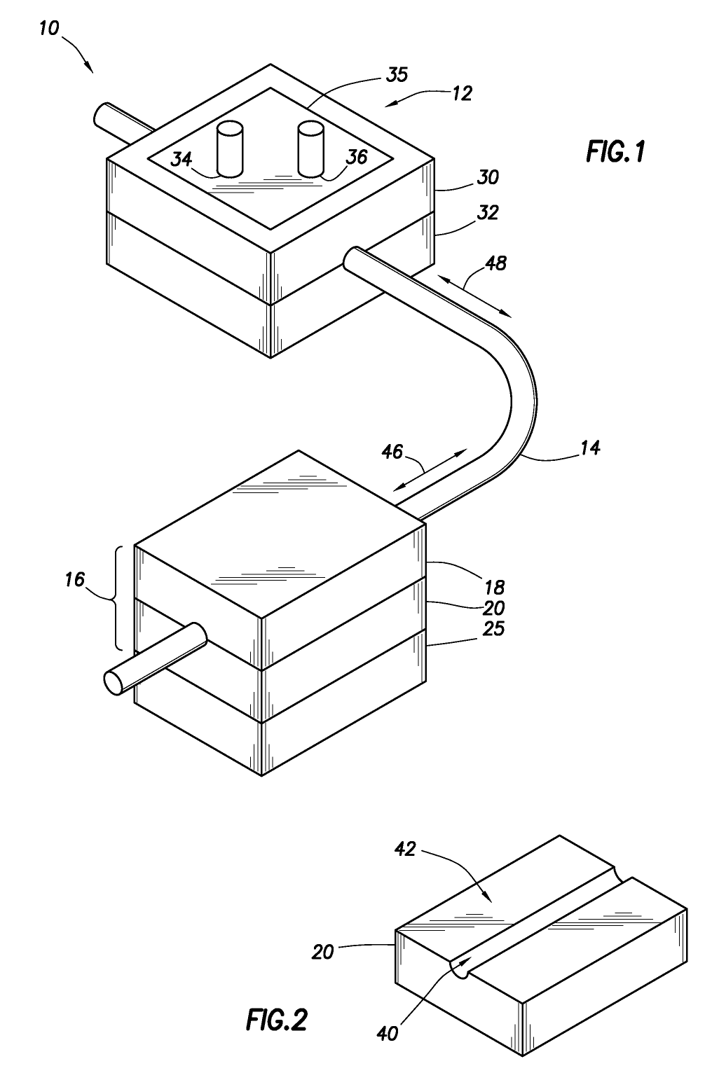

FIG. 1 shows an embodiment of a cooling mechanism 10. The disclosed cooling mechanism comprises a water block 12 and a component block 16. Both of the water block 12 and component block 16 are thermally coupled to a heat pipe 14. The component block 16 is adapted to thermally couple to a heat-producing component 25. In various embodiments, the heat-producing component 25 comprises a processor or other type of component within a system that produces heat. The combination of a water block 12 with the heat pipe 14 avoids having to use a fan for cooling purposes in various embodiments.

Heat produced by the heat-producing component 25 is transferred to the component block 16. Component block 16 transfers the heat to the heat pipe 14. Thus heat from the heat-producing component 25 transfers through the component block 16 to the heat pipe 14. The heat pipe 14 transfers the heat to the water block 12. In this manner, heat produced by the heat-producing component 25 is transferred away from the heat-producing component 25 to the water block 12, which comprises liquid at a temperature lower than the temperature of the heat pipe or its contents, thereby cooling the heat-producing component.

In accordance with various embodiments, the component block 16 comprises at least two portions 18 and 20. The portions 18 and 20 are coupled together. The heat pipe 14 is sandwiched between the portions 18 and 20 in a thermally conductive manner. That is, the heat pipe 14 is thermally coupled to either or both of the portions 18 and 20. In at least some embodiments, the heat pipe 14 resides within a bore formed in one or both of the portions 18 and 20. In various embodiments, the bore comprises a groove formed in either or both of the portions 18, 20. FIG. 2 shows one of the portions 20. In at least one embodiment, component block portions 18, 20 are identical. A groove 40 is provided (e.g., by carving, routing, etching, etc.) in a surface 42 of the portion 20 that mates with the corresponding portion 18. The portion 18 also comprises a groove 40. In at least some embodiments, the heat pipe 14 comprises a cross-sectional shape (e.g., circular) that matches the cross-sectional shape of the grooves 30 formed in portions 18, 20. That the heat pipe 14 resides with the bore formed by the grooves when the portions 18 and 20 are thermally coupled together enables the component block 16 to be attached to the heat pipe 14 at multiple locations on the heat pipe as indicated by arrow 46.

The component block portions 18, 20 are formed from any suitable thermally conductive material. Examples of materials suitable for component block portions 18, 20 comprise copper and aluminum. The portions 18 and 20 are thermally coupled together using any suitable thermally conductive adhesive or other type of coupling mechanism (e.g., screws, bolts, clamps, etc.). The heat-producing component 25 is thermally coupled to component block portion 20 also using any suitable thermally conductive adhesive or other type of coupling mechanism (e.g., screws, bolts, clamps, etc.).

The water block 12 comprises portions 30 and 32. Portion 30 is thermally coupled to portion 32. The portions 30 and 32 also contain a bore formed from grooves provided in portions 30 and 32 similar to that described above regarding portions 18 and 20 of the component block 16. The bore in the water block 12 in which the heat pipe 14 resides enables the water block 12 to be coupled to the heat at multiple locations on the heat pipe as indicated by arrow 48.

The water block 12 also comprises a plate 35 attached to portion 30. A liquid inlet port 34 and an outlet port 36 are provided on plate 35. The water block receives a cold liquid (e.g., water) in through the inlet port 34. The inlet port 34 is coupled to the outlet port 36 via a tube internal to at least one of portions 30 and 32. Heat from the heat pipe 14 transfers through the portions 30 and/or 32 to the cold liquid from the inlet port 34. As a result, the liquid becomes warmer, thereby removing the heat from the heat pipe 14. The warmer liquid flows out of the outlet port 36 and is cooled and recirculated back into the inlet port.

In some embodiments, the liquid used in the water block 12 comprises water. In other embodiments, the liquid is other than water. For purposes of this disclosure, block 12 is referred to as a “water” block regardless of the type of liquid used.

The water block portions 30, 32 are formed from any suitable material. Examples of materials suitable for water block portions 18, 20 comprise copper and aluminum. The portions 30 and 32 are coupled together using any suitable adhesive or other type of coupling mechanism (e.g., screws, bolts, clamps, etc.).

The heat pipe 14 is made from copper, or other suitable material, and comprises a hollow tube in at least some embodiments. A low-boiling liquid is used in the heat pipe 14. As the liquid boils and vaporizes, the vapor transmits the heat through the heat pipe away from the component block 16 and heat-producing component 25 towards the water block 12. The water block 12 causes heat to be exchanged from the heat pipe to the cold liquid. As a result, the vapor in the heat pipe 14 cools and condenses into a liquid state. The resulting liquid in the heat pipe 14 travels back through the heat pipe 14 towards the component block 16. As the liquid in the heat pipe nears the component block 16, the heat from the heat-producing component 25 causes the heat pipe's liquid to boil turning into the vapor state again.

In some embodiments, the cooling mechanism 10 is used in an electronic system such as a computer. The cooling mechanism 10 can be used to cool any heat-producing component within a computer such as the processor as noted above.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A cooling mechanism, comprising:
a heat pipe; and
a water block thermally coupled to said heat pipe.

2. The cooling mechanism of claim 1 further comprising a component block thermally coupled to said heat pipe wherein heat produced by a component transfers through said component block to said heat pipe.

3. The cooling mechanism of claim 2 wherein the component block is attachable to the heat pipe at any of a plurality of locations along the heat pipe.

4. The cooling mechanism of claim 2 wherein the component block comprises a first portion coupled to a second portion, and the heat pipe is sandwiched between said first and second portions.

5. The cooling mechanism of claim 2 wherein the component block comprises a first portion coupled to a second portion, and at least one of the first and second portions comprises a groove in which said heat pipe resides.

6. The cooling mechanism of claim 1 wherein the water block is attachable to the heat pipe at any of a plurality of locations along the heat pipe.

7. The cooling mechanism of claim 1 wherein the water block comprises a first portion coupled to a second portion, and the heat pipe is sandwiched between said first and second portions.

8. The cooling mechanism of claim 6 wherein the water block comprises a first portion coupled to a second portion, and at least one of the first and second portions comprises a groove in which said heat pipe resides.

9. A system, comprising:
a heat-producing component; and
a heat pipe that receives heat from said heat-producing component; and
a water block thermally coupled to said heat pipe.

10. The system of claim 9 wherein the heat-producing component comprises a processor.

11. The system of claim 9 further comprising a component block thermally coupled to said heat-producing component and said heat pipe.

12. The system of claim 11 wherein the component block is attachable to the heat pipe at any of a plurality of locations along the heat pipe

13. The system of claim 11 wherein the component block comprises a first portion coupled to a second portion, and the heat pipe is sandwiched between said first and second portions.

14. The system of claim 11 wherein the component block comprises a first portion coupled to a second portion, and at least one of the first and second portions comprises a groove in which said heat pipe resides.

15. The system of claim 9 wherein the water block is attachable to the heat pipe at any of a plurality of locations along the heat pipe.

16. The system of claim 9 wherein the water block comprises a first portion coupled to a second portion, and the heat pipe is sandwiched between said first and second portions.

17. The system of claim 9 wherein the water block comprises a first portion coupled to a second portion, and at least one of the first and second portions comprises a groove in which said heat pipe resides.

18. A water block, comprising:
a first portion; and
a second portion coupled to said first portion; and
a liquid inlet port provided on at least one of said first and second portions;
wherein at least one of said first and second portions comprises a bore adapted to receive a heat pipe.

19. The water block of claim 18 wherein said bore comprises a groove in at least one of said first and second portions.

20. The water block of claim 18 wherein said bore comprises a groove in both of said first and second portions.
